(19) United States
(12) Patent Application Publication
(10) Pub. No.: US 2024/0315089 A1
(43) Pub. Date: Sep. 19, 2024

(54) DISPLAY APPARATUS, AND DISPLAY PANEL AND MANUFACTURING METHOD THEREFOR

(71) Applicants: Hefei Xinsheng Optoelectronics Technology Co., Ltd., Hefei, Anhui (CN); BOE Technology Group Co., Ltd., Beijing (CN)

(72) Inventors: Jun LIU, Beijing (CN); Yongchao HUANG, Beijing (CN); Li SUN, Beijing (CN); Haidong WANG, Beijing (CN); Yuxuan MA, Beijing (CN); Bin ZHOU, Beijing (CN); Liangchen YAN, Beijing (CN)

(73) Assignees: Hefei Xinsheng Optoelectronics Technology Co., Ltd., Hefei, Anhui (CN); BOE Technology Group Co., Ltd., Beijing (CN)

(21) Appl. No.: 18/277,814

(22) PCT Filed: Nov. 19, 2021
(86) PCT No.: PCT/CN2021/131929

§ 371 Date: Aug. 18, 2023

(30) Foreign Application Priority Data
Mar. 19, 2021 (CN) 202110295047.5

(51) Int. Cl. H10K 59/124; H10K 59/12; H10K 59/131

(52) U.S. Cl. CPC H10K 59/124; H10K 59/1201; H10K 59/131

(57) ABSTRACT

A display device, and a display panel and a manufacturing method therefor, relating to the technical field of display. The display panel includes a substrate, a driver layer, a barrier structure, and a light-emitting layer covering the driver layer and the barrier structure and being discontinuously at least at a barrier groove of the barrier structure. The barrier structure includes a support layer, a barrier layer and a second protective layer. The barrier layer is in a different area of a same film layer than a wiring layer of the driver layer, and a side wall of the barrier layer is provided with the barrier groove surrounding the driver layer. The second protective layer is on a surface of the barrier layer away from the substrate and in a different area of a same protective film than a first protective layer of the driver layer.

### CROSS-REFERENCE TO RELATED APPLICATIONS

The present disclosure is the U.S. National phase application of International Application No. PCT/CN2021/131929, filed on Nov. 19, 2021, which claims priority to Chinese patent application No. 202110295047.5, filed on Mar. 19, 2021, entitled “DISPLAY DEVICE, AND DISPLAY PANEL AND MANUFACTURING METHOD THEREFOR”, the entire contents of each are hereby incorporated herein by reference in their entirety.

### TECHNICAL FIELD

The present disclosure relates to the field of display technologies, and in particular, to a display device, a display panel, and a method for manufacturing a display panel.

### BACKGROUND

At present, Organic Light-Emitting Diode (OLED) display panels have been widely used. Among them, the encapsulation effect directly determines the life and display effect of the OLED display panels. However, the encapsulation effect of existing OLED display panels still needs to be improved, and is prone to problems such as failure of light-emitting devices, which is not conducive to prolonging the service life and affects the display effect.

It should be noted that the above information disclosed in the “BACKGROUND” section is intended only to enhance the understanding of the background of this disclosure, and therefore it may include information that does not constitute prior art known to those of ordinary skill in the art.

### SUMMARY

The purpose of the present disclosure is to provide a display device, a display panel, and a method for manufacturing the display panel.

According to an aspect of the present disclosure, there is provided a display panel, including:

a substrate having a display area, a transition area, and a barrier area, the barrier area being outside of the display area, and the transition area being separated between the display area and the barrier area;

a driver layer, on a side of the substrate and within the display area, including a device layer, a wiring layer and a first protective layer; wherein the wiring layer is on a side of the device layer away from the substrate, and the first protective layer covers the wiring layer and the device layer;

a barrier structure, on the same side of the substrate as the driver layer and in the barrier area, surrounding the driver layer and including a support layer, a barrier layer and a second protective layer; wherein the barrier layer is on a side of the support layer away from the substrate and in a different area of a same film layer than the wiring layer, and a side wall of the barrier layer is provided with a barrier groove surrounding the driver layer; and the second protective layer is on a surface of the barrier layer away from the substrate and in a different area of a same protective film than the first protective layer; and

a light-emitting layer covering the driver layer and the barrier structure and being discontinuously at least at the barrier groove.

In an exemplary embodiment of the present disclosure, the barrier layer is provided with barrier grooves on the side wall close to the driver layer and on the side wall away from the driver layer;

each of the wiring layer and the barrier layer includes a first metal layer, a second metal layer, and a third metal layer stacked in sequence along a direction away from the substrate;

the first metal layer and the third metal layer are of a same material which is different from a material of the second metal layer; and

in the barrier layer, a boundary of an orthographic projection of the second metal layer on the substrate is within boundaries of orthographic projections of the first metal layer and the third metal layer on the substrate to form the barrier groove.

In an exemplary embodiment of the present disclosure, the support layer includes:

a first insulation layer on a side of the substrate;

a first conductive layer on a surface of the first insulation layer away from the substrate; and

a second insulation layer covering a surface of the first conductive layer away from the substrate; and

wherein the barrier layer is on a side of the second insulation layer away from the substrate.

In an exemplary embodiment of the present disclosure, the support layer further includes:

a third insulation layer covering a surface of the second insulation layer away from the substrate; and

wherein the barrier layer is on a side of the third insulation layer away from the substrate.

In an exemplary embodiment of the present disclosure, the support layer further includes:

a second conductive layer on a surface of the third insulation layer away from the substrate; and

a fourth insulation layer covering a surface of the second conductive layer away from the substrate; and

wherein the barrier layer is on a surface of the fourth insulation layer away from the substrate.

In an exemplary embodiment of the present disclosure, the barrier structure further includes:

a first spacer layer on a surface of the second protective layer away from the substrate; and

a second spacer layer on a surface of the first spacer layer away from the substrate.

In an exemplary embodiment of the present disclosure, the device layer includes:

an active layer on a side of the substrate;

a first gate insulation layer covering the active layer and being in a different area of a same film layer than the first insulation layer;

a gate electrode on a surface of the first gate insulation layer away from the substrate, an orthographic projection of the gate electrode on the substrate at least partially overlapping with an orthographic projection of the active layer on the substrate, the gate electrode being in a different area of a same film layer than the first conductive layer;

a second gate insulation layer covering the gate electrode and the first gate insulation layer and being in a different area of a same film layer than the second insulation layer;

an interlayer dielectric layer covering the second gate insulation layer and being in a different area of a same film layer than the third insulation layer;

a source and drain layer, on a surface of the interlayer dielectric layer away from the substrate, comprising a source electrode and a drain electrode connected to the active layer, the source and drain layer being in a different area of a same film layer than the second conductive layer;

a first planarization layer covering the source and drain layer and the interlayer dielectric layer; and

a passivation layer covering the first planarization layer and being in a different area of a same film layer than the fourth insulation layer;

wherein the wiring layer is on a surface of the passivation layer away from the substrate and connected to the source and drain layer;

wherein the driver layer further includes:

a second planarization layer covering the first protective layer; and

wherein the light-emitting layer includes:

a first electrode on a surface of the second planarization layer away from the substrate and connected to the wiring layer, the first electrode being in a different area of a same film layer than the first spacer layer;

a pixel definition layer on the surface of the second planarization layer away from the substrate and exposing the first electrode, the pixel definition layer being in a different area of a same film layer than the second spacer layer;

a light-emitting functional layer covering the pixel definition layer, the first electrode, and the second spacer layer, and being discontinuously at least at the barrier groove; and

a second electrode covering the light-emitting functional layer and being discontinuously at least at the barrier groove.

In an exemplary embodiment of the present disclosure, the film layer in which the first gate insulation layer and the first insulation layer are disposed covers the transition area; and the film layer in which the second gate insulation layer and the second insulation layer are disposed covers the transition area.

In an exemplary embodiment of the present disclosure, a material of the protective film includes at least one of silicon nitride and silicon oxide.

In an exemplary embodiment of the present disclosure, a thickness of the protective film is greater than or equal to 0.1 μm, and is less than or equal to 0.2 μm.

According to an aspect of the present disclosure, there is provided a method for manufacturing a display panel, including:

providing a substrate, wherein the substrate has a display area, a transition area, and a barrier area, the barrier area being outside of the display area, and the transition area being separated between the display area and the barrier area;

forming on a side of the substrate a device layer in the display area and a support layer in the barrier area;

forming, by a single patterning process, a wiring layer on a side of the device layer away from the substrate and a barrier layer on a side of the support layer away from the substrate;

forming a protective film covering the wiring layer and the barrier layer, wherein the protective layer covers side walls of the support layer and the barrier layer;

forming a first electrode in the display area on a side of the protective film away from the substrate;

removing a portion of the protective film disposed on the side walls of the support layer and the barrier layer to obtain a first protective layer and a second protective layer, wherein the first protective layer covers the wiring layer and the device layer, and the second protective layer is disposed on a surface of the barrier layer away from the substrate; forming a barrier groove surrounding the device layer in the side wall of the barrier layer;

forming a pixel definition layer exposing the first electrode on a side of the first protective layer away from the substrate;

forming a light-emitting functional layer covering the pixel definition layer and the first electrode, wherein an orthographic projection of the light-emitting functional layer on the substrate covers the display area and the barrier area, and the light-emitting functional layer is discontinuously at least at the barrier groove; and

forming a second electrode covering the light-emitting functional layer, wherein the second electrode is discontinuously at least at the barrier groove.

In an exemplary embodiment of the present disclosure, forming, by a single patterning process, a wiring layer on a side of the device layer away from the substrate and a barrier layer on a side of the support layer away from the substrate, includes:

forming a first metal layer on the side of the device layer away from the substrate and on the side of the support layer away from the substrate;

forming a second metal layer on a surface of the first metal layer away from the substrate, wherein a material of the second metal layer is different from a material of the first metal layer;

forming a third metal layer on a surface of the second metal layer away from the substrate, wherein a material of the third metal layer is the same as the material of the first metal layer; and

patterning the first metal layer, the second metal layer, and the third metal layer to form the wiring layer on the side of the device layer away from the substrate and the barrier layer on the side of the support layer away from the substrate; and

wherein forming a barrier groove surrounding the device layer in the side wall of the barrier layer, includes:

etching the side wall of the barrier layer by a wet etching process until a boundary of an orthographic projection, of the second metal layer of the barrier layer on the substrate, is within boundaries of orthographic projections, of the first metal layer and the third metal layer on the substrate, to form the barrier groove.

In an exemplary embodiment of the present disclosure, the method further includes:

forming a first spacer layer on a surface of the second protective layer away from the substrate; and

forming a second spacer layer on a surface of the first spacer layer away from the substrate.

In an exemplary embodiment of the present disclosure, the first spacer layer and the first electrode are formed by a single patterning process; and the second spacer layer and the pixel definition layer are formed by a single patterning process.

According to an aspect of the present disclosure, there is provided a display device including a display panel as described in any one of the foregoing embodiments.

It should be understood that the above general description and the following detailed descriptions are exemplary and explanatory only and do not limit the present disclosure.

### BRIEF DESCRIPTION OF THE DRAWINGS

The accompanying drawings herein, being incorporated into and forming part of the specification, show embodiments which are consistent with the present disclosure, and are used in conjunction with the specification to explain the principles of the present disclosure. It will be apparent that the accompanying drawings in the following description are only some of embodiments of the present disclosure, and that other drawings may be obtained from them without creative effort by one of ordinary skill in the art.

FIG. 1 is a schematic diagram of a display panel according to an embodiment of the present disclosure.

FIG. 2 is an electron microscope image of a display panel according to an embodiment of the present disclosure.

FIG. 3 is a flowchart of a manufacturing method according to an embodiment of the present disclosure.

FIG. 4 is a flowchart of step S130 for a display panel according to an embodiment of the present disclosure.

FIG. 5 is a flowchart of a manufacturing method according to another embodiment of the present disclosure.

FIG. 6 is a schematic diagram of a display panel formed corresponding to step S120 of a manufacturing method of an embodiment of the present disclosure.

FIG. 7 is a schematic diagram of a display panel formed corresponding to step S130 of a manufacturing method of an embodiment of the present disclosure.

FIG. 8 is a schematic diagram of a display panel formed corresponding to step S150 of a manufacturing method of an embodiment of the present disclosure.

FIG. 9 is a schematic diagram of a display panel formed corresponding to step S160 of a manufacturing method of an embodiment of the present disclosure.

### DETAILED DESCRIPTION

Exemplary embodiments will now be described more fully with reference to the accompanying drawings. However, the exemplary embodiments can be implemented in a variety of forms and should not be construed as being limited to the embodiments set forth herein; rather, the provision of these embodiments makes the present disclosure comprehensive and complete and conveys the ideas of the exemplary embodiments to those skilled in the art in a comprehensive manner. The same reference numerals in the drawings indicate the same or similar structures, and thus their detailed description will be omitted. In addition, the accompanying drawings are only schematic illustrations of the present disclosure and are not necessarily drawn to scale.

Although relative terms such as “on or above” and “under or below” are used in this specification to describe the relative relationship of one component of the sign to another, these terms are used in this specification only for convenience, for example, according to the direction of the examples described in the accompanying drawings. It should be understood that if the device of the sign is inverted so that it is upside down, the component described as being “on” will become the component described as being “below”. When a structure is “on” another structure, it may mean that the structure is integrally formed on another structure, or that the structure is “directly” arranged on another structure, or that the structure is “indirectly” arranged on another structure through yet another structure.

The terms “a/an”, “one”, “the”, “said” and “at least one” are used to indicate the existence of one or more elements/components/etc. The terms “including” and “having” are used to indicate open-ended inclusion and to mean that additional elements/components/etc. may exist in addition to the listed elements/components/etc. The terms “first”, “second” and “third” are used as markers only and are not limitations on the number of objects thereof.

According to an embodiment of the present disclosure, a display panel is provided, which may be an OLED display panel. As shown in FIG. 1, the display panel may include a substrate 1, a driver layer 2, a barrier structure 3, and a light-emitting layer 4.

In this embodiment, the substrate 1 has a display area 101, a transition area 102, and a barrier area 103. The barrier area 103 is disposed outside the display area 101. The transition area 102 is separated between the display area 101 and the barrier area 103.

The driver layer 2 is disposed on a side of the substrate 1 and is disposed within the display area 101. The driver layer 2 includes a device layer 21, a wiring layer 22, and a first protective layer 23. The wiring layer 22 is disposed on a side of the device layer 21 away from the substrate 1. The first protective layer 23 covers the wiring layer 22 and the device layer 21.

The barrier structure 3 is disposed on the same side of the substrate 1 as the driver layer 2 and is located in the barrier area 103 and surrounds the driver layer 2. The barrier structure 3 includes a support layer 31, a barrier layer 32, and a second protective layer 33. The barrier layer 32 is disposed on a side of the support layer 31 away from the substrate 1 and is disposed in a different area of the same film layer than the wiring layer 22. The side wall of the barrier layer 32 is provided with a barrier groove 321 surrounding the driver layer 2. The second protective layer 33 is disposed on a surface of the barrier layer 32 away from the substrate 1. The second protective layer 33 and the first protective layer 23 are disposed in different areas of the same protective film 100.

The light-emitting layer 4 covers the driver layer 2 and the barrier structure 3 and is disposed discontinuously at least at the barrier groove 321.

In the display panel of this embodiment of the present disclosure, when forming the light-emitting layer 4, the light-emitting layer 4 cannot be formed inside the barrier groove 321, so that the light-emitting layer 4 can be ensured to be disconnected at least at the barrier groove 321, thereby cutting off the path for water and oxygen to intrude into the area corresponding to the display area 101 in the display panel along the light-emitting layer 4, and preventing the failure of the light-emitting layer 4 due to erosion and guaranteeing the display effect.

The display panel of the present disclosure is described in detail below.

As shown in FIGS. 1 and 6-9, the substrate 1 may play a load-bearing role, and it may be a single-layer or multi-layer structure. Taking the multi-layer structure of the substrate as an example, the substrate 1 may include a base layer and a buffer layer formed on the base layer. The material of the base layer may include hard materials such as glass, or flexible materials such as polyimide. The buffer layer may be a single-layer or multi-layer structure, and the material thereof may include silicon nitride, silicon oxide, and so on, for example, the buffer layer may include a silicon nitride layer and a silicon oxide layer. The thickness of the silicon nitride layer may range from 0.3 μm to 0.7 μm. The thickness of the silicon oxide layer may range from 1 μm to 1.2 μm.

The substrate 1 may be divided into a plurality of areas including a display area 101, a transition area 102, and a barrier area 103. The transition area 102 is disposed outside of the display area 101. The barrier area 103 is disposed outside of the transition area 102, and the display area 101 may be separated from the barrier area 103 by the transition area 102. Further, the display area 101 and the barrier area 103 may be connected by the transition area 102. In the display panel, an area corresponding to the display area 101 may be used for light emission.

The driver layer 2 is disposed on a side of the substrate 1 and is disposed within the display area 101, i.e. an orthographic projection of the driver layer 2 on the substrate 1 is located within the display area 101. The driver layer 2 can be used to drive the light-emitting layer 4 to emit light so as to display an image. Specifically, the driver layer 2 may include a device layer 21, a wiring layer 22, and a first protective layer 23. The wiring layer 22 is disposed on a side of the device layer 21 away from the substrate 1. The first protective layer 23 covers the wiring layer 22 and the device layer 21.

The device layer 21 is disposed on a side of the substrate 1 and is disposed within the display area 101. The display area 101 may include a light-emitting area and an edge area surrounding the light-emitting area. The device layer 21 may include a driving circuit, and the driving circuit may include a pixel circuit located within the light-emitting area and an edge circuit located within the edge area. The edge circuit may include a gate driving circuit and a light-emitting control circuit that are connected to the pixel circuit, etc. The light-emitting layer 4 may be driven to emit light through the driving circuit. The driving circuit may include a plurality of transistors and capacitors and other components, and taking a top-gate type thin film transistor as an example, the device layer 21 may include an active layer 210, a first gate insulation layer 211, a gate electrode 212, a second gate insulation layer 213, an interlayer dielectric layer 214, a source and drain layer 215, a first planarization layer 216, and a passivation layer 217.

The active layer 210 is disposed on a side of the substrate 1 and is disposed in the display area 101, and the material thereof may be polycrystalline silicon, amorphous silicon, or a metal oxide, which is not specifically limited herein. For example, an amorphous silicon (α-Si) layer may be formed on one side of the substrate 1, the thickness of which may be 0.05 μm; after the amorphous silicon layer is subjected to a dehydrogenation process, the amorphous silicon layer may be crystallized to be converted into a polysilicon layer, e.g., the amorphous silicon layer may be converted into the polysilicon layer by excimer laser annealing (ELA) under a temperature of 300° C. to 350° C. The amorphous silicon after dehydrogenation is less prone to hydrogen explosion during excimer laser annealing. Subsequently, a silicon island mask can be formed by using a digital exposure machine or mask, and then dry etching can be carried out to obtain the silicon island, for example, the active layer 210 can be obtained by dry etching with hydrogen tetra fluoride (CF₄) and oxygen (O₂) and wet stripping of the silicon island mask to form a silicon island pattern. Then, the capacitive region of the active layer 210 can be implanted with ions to make it conductive, and the ion implantation can be carried out using phosphorane or borane during doping.

The first gate insulation layer 211 covers the active layer 210. The first gate insulation layer 211 may be a single-layer or multi-layer structure. For example, the first gate insulation layer 211 may include a silicon oxide layer and a silicon nitride layer, and the silicon oxide layer may have a thickness ranging from 0.03 μm to 0.06 μm, and the silicon nitride layer may have a thickness ranging from 0.05 μm to 0.09 μm.

The gate electrode 212 is disposed on a surface of the first gate insulation layer 211 away from the substrate 1, and an orthographic projection of the gate electrode 212 on the substrate 1 at least partially overlaps with an orthographic projection of the active layer 210 on the substrate 1. The material of the gate electrode 212 may be metal, e.g. molybdenum, and may have a thickness ranging from 0.25 μm to 0.3 μm. A gate mask can be formed using a digital exposure machine or mask, and thereafter, dry etching can be performed using sulfur tetra fluoride (SF₆) and oxygen, or can be performed using a mixture of carbon tetra fluoride (CF₄) and oxygen, with a flow rate of 2000 sccm to 2500 sccm for CF₄ and 1000 sccm to 1500 sccm for oxygen. After dry etching, the active layer 210 used to contact the source and drain electrodes can be doped using a gate self-alignment process to conductorize it, and for the doping process, phosphane or borane may be used, and then, the gate mask is removed by wet stripping, and then annealing is performed to repair the active layer 210 and the first gate insulation layer 211 that have been damaged by the ionic doping, and the annealing temperature may range from 500° C. to 600° C.

The second gate insulation layer 213 covers the gate electrode 212 and the first gate insulation layer 211. The interlayer dielectric layer 214 covers the second gate insulation layer 213, and the interlayer dielectric layer 214 may be a single-layer or multi-layer structure. Taking the multi-layer structure of the interlayer dielectric layer as an example, it may include a silicon nitride layer and a silicon oxide layer, and a thickness of the silicon oxide layer may range from 0.2 μm to 0.5 μm and a thickness of the silicon nitride layer may range from 0.2 μm to 0.3 μm.

The source and drain layer 215 is disposed on a surface of the interlayer dielectric layer 214 away from the substrate 1, and includes a source electrode 215S and a drain electrode 215D connected to the active layer 210. The source electrode 215S and the drain electrode 215D are connected to the active layer 210 through via holes from both sides of the gate 212. After forming the interlayer dielectric layer 214, via holes may be formed in the interlayer dielectric layer 214 by a dry etching process, in order to connect the source and drain layer 215 to the active layer 210. The source and drain layer 215 may be a single-layer or multi-layer structure. Taking the multi-layer structure of the source and drain layer as an example, the source and drain layer 215 may include two titanium metal layers and an aluminum metal layer disposed between the two titanium metal layers, and the thickness of the titanium metal layer may range from 300 nm to 600 nm and the thickness of the aluminum metal layer may range from 6,000 nm to 6,500 nm. Of course, other metals may also be used. During forming the source and drain layer 215, a digital exposure machine or a mask can be used to form a source and drain mask, and it can be etched with boron trichloride (BCl₃) and chlorine gas (Cl₂).

The first planarization layer 216 covers the source and drain layer 215 and the interlayer dielectric layer 214. The material of the first planarization layer 216 may include a transparent resin or other material and may be formed sequentially by a coating, exposure, developing, and baking process. The thickness of the first planarization layer 216 may range from 1.5 μm to 2 μm.

The passivation layer 217 covers the first planarization layer 216. The material of the passivation layer 217 may include silicon nitride. A pattern of the passivation layer 217 may be formed by dry etching. The thickness of the passivation layer 217 may range from 0.1 μm to 0.2 μm.

In addition, the device layer 21 may further include a lead layer 218, which may be disposed on a surface of the second gate insulation layer 213 away from the substrate 1 and covered by the interlayer dielectric layer 214. A portion of the lead layer 218 may be connected to the source and drain layer 215.

The wiring layer 22 is disposed on a surface of the device layer 21 away from the substrate 1 and connected to the source and drain layer 215, e.g., the wiring layer 22 is disposed on a surface of the passivation layer 217 away from the substrate 1. The wiring layer 22 is made of the same material as the source and drain layer 215, and the wiring layer 22 may be a multi-layer structure, which may include a first metal layer 001, a second metal layer 002, and a third metal layer 003 stacked sequentially in a direction away from the substrate 1, as shown in FIGS. 1 and 7. The first metal layer 001 and the third metal layer 003 are made of the same material which is different from the material of the second metal layer 002. In the wiring layer 22, the boundaries of orthographic projections of the first metal layer 001, the second metal layer 002, and the third metal layer 003 on the substrate 1 overlap, and the thickness of the first metal layer 001 may be the same as that of the second metal layer 002.

For example, the material of the first metal layer 001 and the third metal layer 003 may be titanium, and the material of the second metal layer 002 may be aluminum; and the thicknesses of the first metal layer 001 and the third metal layer 003 are the same and may range from 300 nm to 600 nm, and the thickness of the second metal layer 002 may range from 6,000 nm to 6,500 nm. The manner of forming the wiring layer 22 may be referred to as the manner of forming the source and drain layer 215, and will not be described herein. In order to protect the wiring layer 22 and the barrier layer 32, a protective film 100 covering the wiring layer 22 and the barrier layer 32 may be formed, and then the light-emitting layer 4 may be formed.

The first protective layer 23 covers the wiring layer 22 and covers a surface of the device layer 21 that is not covered by the wiring layer 22. An orthographic projection of the first protective layer 23 on the substrate 1 covers the display area 101 and has no overlapping area with the transition area 102. The material of the first protective layer 23 may include at least one of silicon nitride and silicon oxide. The thickness of the first protective layer 23 is greater than or equal to 0.1 μm and less than or equal to 0.2 μm.

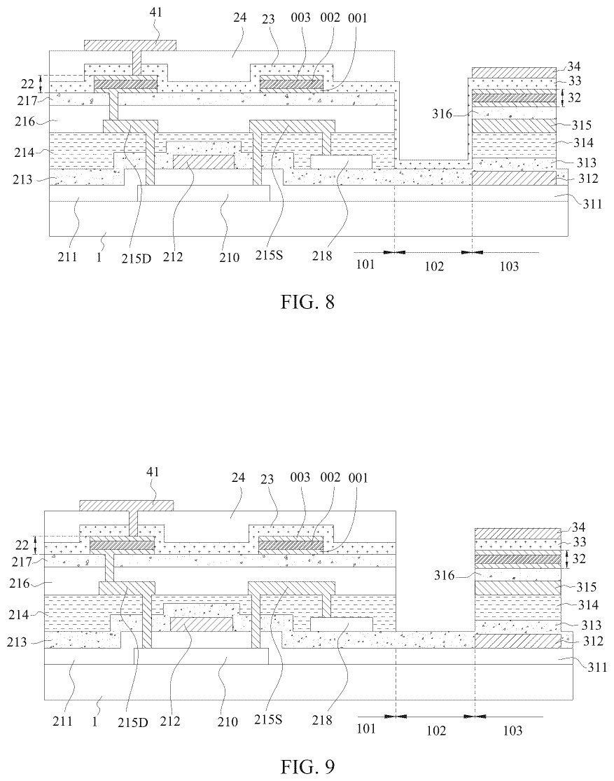

In addition, as shown in FIGS. 1 and 8, the display panel of the present disclosure may further include a second planarization layer 24, which covers the first protective layer 23. An orthographic projection of the second planarization layer 24 on the substrate 1 is located within the display area 101.

The barrier structure 3 is disposed on the same side of the substrate 1 as the driver layer 2 and is located in the barrier area 103 and surrounds the driver layer 2. For example, the barrier structure 3 may be a ring-shaped rib structure and is disposed around the driver layer 2 for blocking the light-emitting layer 4. Alternatively, a portion of the boundaries of the driver layer 2 overlap with the boundaries of the display panel, and in this case, the barrier structure 3 may be a semi-closed rib structure such as a semicircle, at least surrounding a portion of the driver layer 2. In addition, the barrier structure 3 may include a support layer 31, a barrier layer 32, and a second protective layer 33.

The support layer 31 is configured to support the barrier layer 32 to increase the height of the barrier layer 32, in order to increase the climbing difficulty of the light-emitting layer 4, facilitate the disconnection of the light-emitting layer 4 at the side wall of the barrier structure 3, and cut off the paths of the water and oxygen erosion.

In some embodiments of the present disclosure, the support layer 31 may include a first insulation layer 311, a first conductive layer 312, and a second insulation layer 313.

The first insulation layer 311 is disposed on a side of the substrate 1. The first insulation layer 311 may be disposed in the same layer as the first gate insulation layer 211, i.e., the first insulation layer 311 and the first gate insulation layer 211 are located in different areas of the same film layer, and thus may be formed simultaneously in order to simplify the process. In this case, an orthographic projection, of the film layer in which the first insulation layer 311 and the first gate insulation layer 211 are located, on the substrate 1, may cover the transition area 102, so that the film layer in which the first insulation layer 311 and the first gate insulation layer 211 are located is continuous in the transition area 102.

The first conductive layer 312 is disposed on a surface of the first insulation layer 311 away from the substrate 1, and the first conductive layer 312 is disposed in the same layer as the gate electrode 212, i.e., the first conductive layer 312 and the gate electrode 212 are located in different areas of the same film layer, and thus can be formed simultaneously in order to simplify the process. In this case, the first conductive layer 312 and the gate electrode 212 are not connected to each other, and the first conductive layer 312 may cause the first insulation layer 311 to protrude in an area corresponding to the first conductive layer 312, which is conductive to raising the height of the support layer 31, thereby facilitating the raising of the height of the entire barrier structure 3, and improving the climbing difficulty of the light-emitting layer 4, so that the light-emitting layer 4 can be more easily disconnected at the side wall of the barrier structure 3, and thus cutting off the erosion path of the water and oxygen.

The second insulation layer 313 covers a surface of the first conductive layer 312 away from the substrate 1. The second gate insulation layer 213 is disposed in the same layer as the second insulation layer 313, i.e., they are located in different areas of the same film layer, so that they can be formed simultaneously in order to simplify the process. In this case, an orthographic projection, of the film layer in which the second insulation layer 313 and the second gate insulation layer 213 are located, on the substrate 1, covers the transition area 102, so that the film layer in which the second insulation layer 313 and the second gate insulation layer 213 are located is continuous in the transition area 102.

The support layer 31 may further include a third insulation layer 314 which covers a surface of the second insulation layer 313 away from the substrate 1. The interlayer dielectric layer 214 and the third insulation layer 314 are disposed in the same layer, i.e., they are located in different areas of the same film layer. In this case, the film layer in which the interlayer dielectric layer 214 and the third insulation layer 314 are located may be disconnected in an area corresponding to the transition area 102. That is, an orthographic projection on the substrate 1 of the film layer in which the interlayer dielectric layer 214 and the third insulation layer 314 are located does not cover the transition area 102.

The support layer 31 may further include a second conductive layer 315 and a fourth insulation layer 316.

In this case, the second conductive layer 315 is disposed on a surface of the third insulation layer 314 away from the substrate 1. The second conductive layer 315 is disposed in the same layer as the source and drain layer 215, i.e., the second conductive layer 315 and the source and drain layer 215 are located in different areas of the same film layer and are not connected to each other, so that they can be formed simultaneously in order to simplify the process.

The fourth insulation layer 316 covers a surface of the second conductive layer 315 away from the substrate 1. The fourth insulation layer 316 is disposed in the same layer as the passivation layer 217, i.e., they are located in different areas of the same film layer. In this case, the fourth insulation layer 316 and the passivation layer 217 may be disconnected in an area corresponding to the transition area 102. That is, an orthographic projection on the substrate 1 of the film layer in which the fourth insulation layer 316 and the passivation layer 217 are located does not cover the transition area 102, which facilitates the separation of the driver layer 2 and the barrier structure 3.

The second conductive layer 315 may cause the fourth insulation layer 316 to protrude in an area corresponding to the second conductive layer 315, which is conductive to raising the height of the support layer 31, thereby facilitating the raising of the height of the entire barrier structure 3, and improving the climbing difficulty of the light-emitting layer 4, so that the light-emitting layer 4 can be more easily disconnected at the side wall of the barrier structure 3, and thus cutting off the erosion path of the water and oxygen.

The barrier layer 32 is disposed on a side of the support layer 31 away from the substrate 1. For example, the barrier layer 32 is disposed on a surface of the fourth insulation layer 316 away from the substrate 1. A side wall of the barrier layer 32 is provided with a barrier groove 321 surrounding the driver layer 2. Further, the barrier layer 32 is provided with barrier grooves 321 on the side wall close to the driver layer 2 and on the side wall away from the driver layer 2. Of course, the barrier groove 321 may be provided on either of the side wall close to the driver layer 2 and the side wall away from the driver layer 2. When forming the light-emitting layer 4, the material of the light-emitting layer 4 cannot be formed inside the barrier groove(s) 321, so that the light-emitting layer 4 can be ensured to be disconnected at least at the barrier groove(s) 321, thereby cutting off the erosion path of the water and oxygen.

The barrier layer 32 is disposed in the same layer as the wiring layer 22 of the driver layer 2, i.e., the barrier layer 32 is located in a different area of the same film layer than the wiring layer 22. Accordingly, in some embodiments of the present disclosure, the barrier layer 32 may include a first metal layer 001, a second metal layer 002, and a third metal layer 003 stacked sequentially in a direction away from the substrate 1.

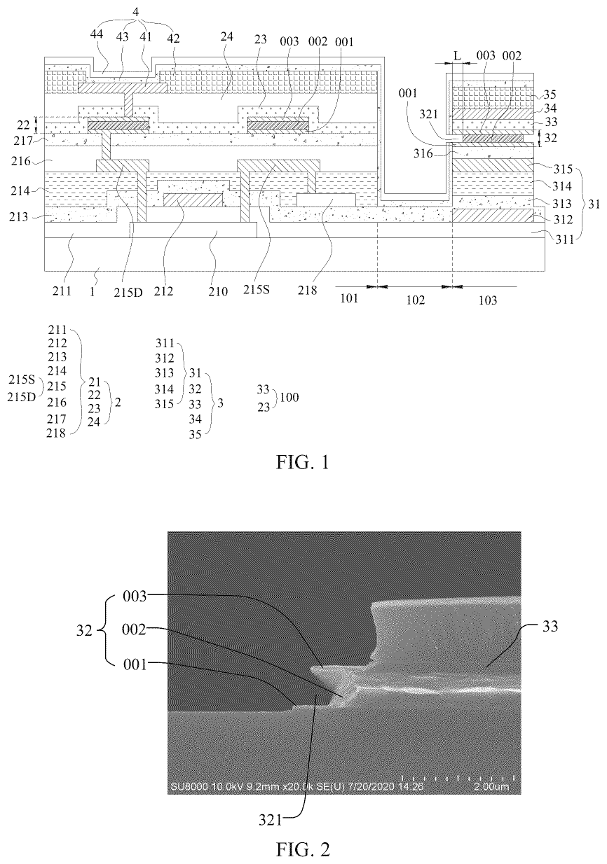

The first metal layer 001 and the third metal layer 003 are made of the same material which is different from the material of the second metal layer 002. For example, the material of the first metal layer 001 and the third metal layer 003 may be titanium, and the material of the second metal layer 002 may be aluminum. The boundaries of the orthographic projections of the first metal layer 001 and the third metal layer 003 on the substrate 1 overlap; and the boundary of the orthographic projection of the second metal layer 002 on the substrate 1 is located within the boundaries of the orthographic projections of the first metal layer 001 and the third metal layer 003 on the substrate 1, such that an edge of the second metal layer 002 is inwardly retracted with respect to the edges of the first metal layer 001 and the second metal layer 002 to form a cross-section in a “ [symbol] ” shape, as shown in FIG. 2. That is, the edges of the first metal layer 001 and the third metal layer 003 are disposed outside the second metal layer 002, but do not collapse, thereby forming the barrier groove 321. Further, in order to avoid the collapse of the third metal layer 003 without the formation of the light-emitting layer 4 in the barrier groove 321, the depth L of the barrier groove 321 may range from 0.5 μm to 0.65 μm, which is a length of the third metal layer 003 extending out of the second metal layer 002.

The second protective layer 33 covers a surface of the barrier layer 32 away from the substrate 1, and the second protective layer 33 is disposed in the same layer as the first protective layer 23, i.e., they are located in different areas of the same film layer (i.e., the protective film 100). Accordingly, the thickness and material of the second protective layer 33 is the same as that of the first protective layer 23, and will not be described in detail herein.

As shown in FIG. 8, it should be noted that the protective film 100 may be configured to protect the wiring layer 22 and the barrier layer 32, in order to prevent damage to the wiring layer 22 and the barrier layer 32 caused by the developer solution during the formation of the second planarization layer 24 and the etching solution during the formation of the first electrode 41, and ensure the structural stability of the barrier groove 321. After forming the wiring layer 22 and the barrier layer 32, the protective film 100 may cover the wiring layer 22 and the barrier layer 32, and the protective film 100 covers the side wall of the driver layer 2, the side wall of the support layer 31, and the side wall of the barrier layer 32 within the range of the transition area 102. As shown in FIG. 9, after forming the first electrode 41, the protective film 100 within the transition area 102 may be removed to obtain the first protective layer 23 and the second protective layer 33, thereby exposing the side walls of the support layer 31 and the barrier layer 32, and forming the barrier groove 321 on the side wall of the barrier layer 32.

In order to enhance the blocking effect, in some embodiments of the present disclosure, a plurality of barrier structures 3 may be provided and be sequentially spaced apart in a direction of away from the driver layer 2, and all of them are surrounded outside of the driver layer 2, but the sizes of the two neighboring barrier structures 3 are different. In this case, the barrier structures 3 of the present disclosure may be applicable to display panels of various shapes, such as, rectangular, circular, elliptical, and the like, as long as they can be surrounded outside the driver layer 2 and block the light-emitting layer 4.

The light-emitting layer 4 covers the driver layer 2 and the barrier structure 3, and is discontinuously at least at the barrier groove 321, i.e., the light-emitting layer 4 cannot be formed within the barrier groove 321 and is thus disconnected by the presence of the barrier structure 3. In addition, due to the height of the support layer 31, the barrier layer 32, the second protective layer 33, as well as the first spacer layer 34 and the second spacer layer 35 mentioned above, it is more difficult to form the light-emitting layer 4 on the side wall of the barrier structure 3, so that the light-emitting layer 4 will not be formed not only in the barrier groove 321, but even on the side wall where the barrier groove 321 is located, cutting off the erosion path of the water and oxygen to the greatest extent possible.

In some embodiments of the present disclosure, the light-emitting layer 4 may include a plurality of light-emitting devices, which may be OLEDs. Taking one light-emitting device as an example, the light-emitting layer 4 may include a first electrode 41, a pixel definition layer 42, a light-emitting functional layer 43, and a second electrode 44.

In this case, the first electrode 41 is disposed on a surface of the second planarization layer 24 away from the substrate 1 and is connected to the wiring layer 22. The first electrode 41 serves as an OLED anode, which may be a single-layer or multi-layer structure, for example, the first electrode 41 may include a first transparent conductive layer, a conductive metal layer, and a second transparent conductive layer stacked sequentially in a direction away from the substrate 1. The first transparent conductive layer and the second transparent conductive layer are of the same material, and may be made of indium tin oxide (ITO) or other transparent conductive material. The conductive metal layer may be made of a material such as metallic silver and other materials.

The pixel definition layer 42 is disposed on a surface of the second planarization layer 24 away from the substrate 1 and exposes the first electrode 41. For example, the pixel definition layer 42 is provided with an opening by which the first electrode 41 is exposed, and an orthographic projection of the opening on the substrate 1 is located within a range of an orthographic projection of the first electrode 41 on the substrate 1. For example, the material of the pixel definition layer 42 may include a resin, which may have a thickness ranging from 1.4 μm to 1.8 μm, and may be formed sequentially by a coating, exposure, developing, and baking process.

In order to protect the wiring layer 22 and the barrier layer 32, the protective film 100 covering the wiring layer 22 and the barrier layer 32 may be formed. After the wiring layer 22 and the barrier layer 32 are formed and before the first electrode 41 is formed, the wiring layer 22 and the barrier layer 32 are protected by the protective film 100, in order to prevent damage to the wiring layer 22 and the barrier layer 32 caused by the developer solution during the formation of the second planarization layer 24 and the etching solution during the formation of the first electrode 41. The protective film 100 covers the wiring layer 22 and the barrier layer 32, and the second planarization layer 24 and the first spacer layer 34 are disposed on a surface of the protective film 100 away from the substrate 1.

In order to further ensure that the light-emitting layer 4 is cut off by the barrier structure 3 and to simplify the process, the height of the barrier structure 3 may be increased using a process of forming the first electrode 41 and the pixel definition layer 42. For example, in some embodiments of the present disclosure, the barrier structure 3 may further include a first spacer layer 34 and a second spacer layer 35.

In this case, the first spacer layer 34 may be disposed on a surface of the second protective layer 33 away from the substrate 1. The first electrode 41 is disposed in the same layer as the first spacer layer 34, i.e., the first electrode 41 and the first spacer layer 34 are located in different areas of the same film layer. In addition, an orthographic projection on the substrate 1 of the film layer in which the first spacer layer 34 and the first electrode 41 are located does not cover the transition area 102.

The second spacer layer 35 is disposed on a surface of the first spacer layer 34 away from the substrate 1, and the pixel definition layer 42 is disposed on the same layer as the second spacer layer 35, i.e., the pixel definition layer 42 and the second spacer layer 35 are located in different areas of the same film layer. In addition, an orthographic projection on the substrate 1 of the film layer in which the second spacer layer 35 and the pixel definition layer 42 are located does not cover the transition area 102, so as to make the spacer layer and the pixel definition layer 42 disconnect in the transition area 102, and to facilitate disconnection of the light-emitting layer 4.

The height of the barrier structure 3 may be further increased by the first spacer layer 34 and the second spacer layer 35 to prevent the light-emitting layer 4 from being continuous on the side wall of the barrier structure 3.

The light-emitting functional layer 43 may include an organic light-emitting material, which may cover the pixel definition layer 42, the first electrode 41, and the second spacer layer 35, and is discontinuously provided at least at the barrier groove 321 to disconnect the path of water and oxygen intrusion. For example, the light-emitting functional layer 43 may include a hole-injection layer, a hole-transport layer, a light-emitting material layer, an electron-transport layer, and an electron-injection layer stacked sequentially in a direction away from the substrate 1, each of which is disconnected at the barrier groove 321.

The second electrode 44 covers the light-emitting functional layer 43 and is discontinuously provided at least at the barrier groove 321. An encapsulation layer covers the second electrode 44. The second electrode 44 may be a single-layer or multi-layer structure, and the material thereof may include a metal, a metal oxide, and the like, which is not specifically limited herein. Each light-emitting device may share the second electrode 44, i.e., the second electrode 44 may be a film layer covering the light-emitting functional layer 43, and serve as a cathode of each light-emitting device. Due to the presence of the barrier groove 321, the second electrode 44 is disconnected at the barrier groove 321 to avoid the second electrode 44 acting as a path for water and oxygen erosion. Before forming the light-emitting functional layer 43, the barrier layer 32 and the wiring layer 22 may be covered by the protective film 100 to prevent the barrier layer 32 and the wiring layer 22 from being damaged and to avoid affecting the formation of the barrier groove 321, thereby ensuring that the barrier groove 321 can disconnect the light-emitting functional layer 43 and the second electrode 44, preventing the water and oxygen from eroding along the light-emitting functional layer 43 and the second electrode 44 toward the display area 101, and thus improving the encapsulation effect.

In addition, the display panel of the present disclosure may further include the encapsulation layer, which may cover the light-emitting layer 4 for protecting the respective light-emitting devices of the light-emitting layer 4. Further, the encapsulation layer may also cover the barrier structure 3 and be continuous within the transition area 102. In some embodiments of the present disclosure, the encapsulation may be realized by means of Thin-Film Encapsulation (TFE). Specifically, the encapsulation layer may include a first inorganic layer, an organic layer, and a second inorganic layer. The first inorganic layer covers a surface of the light-emitting layer 4 away from the substrate 1. The organic layer may be disposed on a surface of the first inorganic layer away from the substrate 1, a boundary of which is defined on the inside of a boundary of the first inorganic layer. The second inorganic layer covers the organic layer and the first inorganic layer that is not covered by the organic layer, and the water and oxygen intrusion can be blocked by the second inorganic layer. In addition, planarization can be achieved through the flexible organic layer. Further, an orthographic projection of the organic layer on the substrate 1 may be located within the display area 101, and orthographic projections of the first inorganic layer and the second inorganic layer on the substrate 1 may cover the display area 101, the transition area 102, and the barrier area 103.

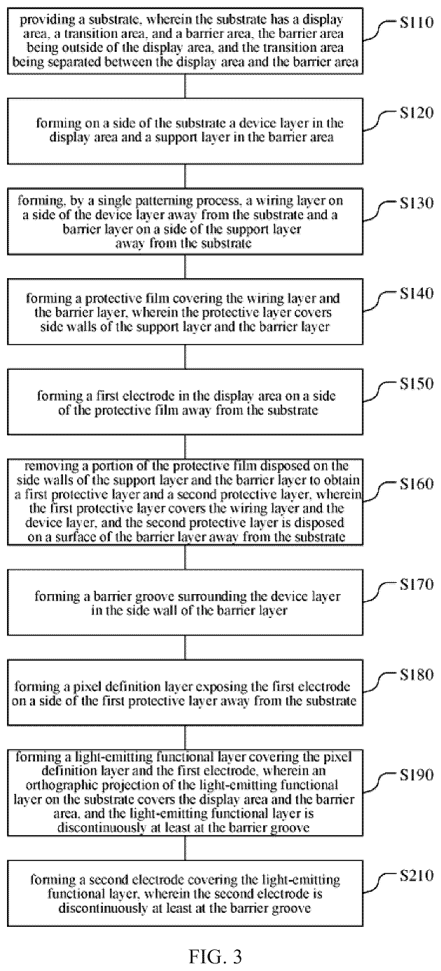

According to some embodiments of the present disclosure, a method for manufacturing a display panel is provided. The display panel is the display panel of any of the above embodiments, the structure and beneficial effects of which can be referred to the embodiments of the display panel, and will not be repeated herein. As shown in FIG. 3, the manufacturing method of the present disclosure may include steps S110 to S220.

Step S110, providing a substrate, wherein the substrate has a display area, a transition area, and a barrier area, the barrier area being outside of the display area, and the transition area being separated between the display area and the barrier area.

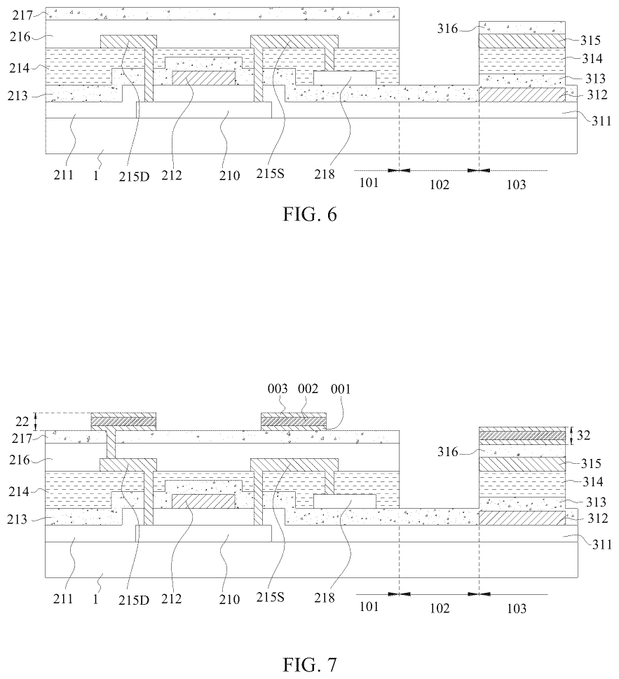

Step S120, forming on a side of the substrate a device layer in the display area and a support layer in the barrier area. In some embodiments, the structure formed after step 120 is shown in FIG. 6.

Step S130, forming, by a single patterning process, a wiring layer on a side of the device layer away from the substrate and a barrier layer on a side of the support layer away from the substrate. In some embodiments, the structure formed after step 130 is shown in FIG. 7.

Step S140, forming a protective film covering the wiring layer and the barrier layer, wherein the protective layer covers side walls of the support layer and the barrier layer.

Step S150, forming a first electrode in the display area on a side of the protective film away from the substrate. In some embodiments, the structure formed after step 150 is shown in FIG. 8.

Step S160, removing a portion of the protective film disposed on the side walls of the support layer and the barrier layer to obtain a first protective layer and a second protective layer, wherein the first protective layer covers the wiring layer and the device layer, and the second protective layer is disposed on a surface of the barrier layer away from the substrate. In some embodiments, the structure formed after step 160 is shown in FIG. 9.

Step S170, forming a barrier groove surrounding the device layer in the side wall of the barrier layer.

Step S180, forming a pixel definition layer exposing the first electrode on a side of the first protective layer away from the substrate.

Step S190, forming a light-emitting functional layer covering the pixel definition layer and the first electrode, wherein an orthographic projection of the light-emitting functional layer on the substrate covers the display area and the barrier area, and the light-emitting functional layer is discontinuously at least at the barrier groove.

Step S210, forming a second electrode covering the light-emitting functional layer, wherein the second electrode is discontinuously at least at the barrier groove.

In the manufacturing method of the present disclosure, the wiring layer and the barrier layer may be covered by the protective film after the wiring layer and the barrier layer are formed and before the barrier groove is formed, and the barrier groove is formed after the pixel definition layer and the first electrode are formed so that the light-emitting functional layer and the second electrode are disconnected on the side wall of the barrier layer, thereby preventing damage to the barrier layer and the wiring layer caused by the process of forming the pixel definition layer and the first electrode layer. When the display panel further includes the second planarization layer as described above, the protective film is formed before forming the second planarization layer, so that damage to the wiring layer and the barrier layer can be avoided when forming the second planarization layer and the first electrode.

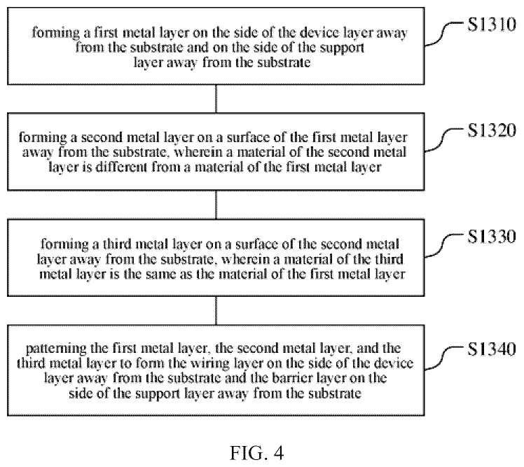

According to some embodiments of the present disclosure, step S130 may include steps S1310 to S1330, as shown in FIG. 4.

Step S1310, forming a first metal layer on the side of the device layer away from the substrate and on the side of the support layer away from the substrate.

Step S1320, forming a second metal layer on a surface of the first metal layer away from the substrate, wherein a material of the second metal layer is different from a material of the first metal layer.

Step S1330, forming a third metal layer on a surface of the second metal layer away from the substrate, wherein a material of the third metal layer is the same as the material of the first metal layer.

Step S1340, patterning the first metal layer, the second metal layer, and the third metal layer to form the wiring layer on the side of the device layer away from the substrate and the barrier layer on the side of the support layer away from the substrate.

Further, in some embodiments of the present disclosure, step S170 may include:

etching the side wall of the barrier layer by a wet etching process until a boundary of an orthographic projection, of the second metal layer of the barrier layer on the substrate, is within boundaries of orthographic projections, of the first metal layer and the third metal layer on the substrate, to form the barrier groove.

For example, the first metal layer and the third metal layer of the barrier layer are made of titanium, and the second metal layer of the barrier layer is made of aluminum, and a molybdenum-specific etching solution can be used for wet etching, which may include 10%-20% acetic acid (CH₃COOH), 1%-2.5% nitric acid (HNO₃), and 50%-60% phosphoric acid (H₃PO₄). When the barrier layer exposed by the protective film is wet etched using this etching solution, the second metal layer can be retracted to form a structure in a “ [symbol] ” shape to obtain the barrier groove since the etching rate of the etching solution on aluminum is greater than that of titanium.

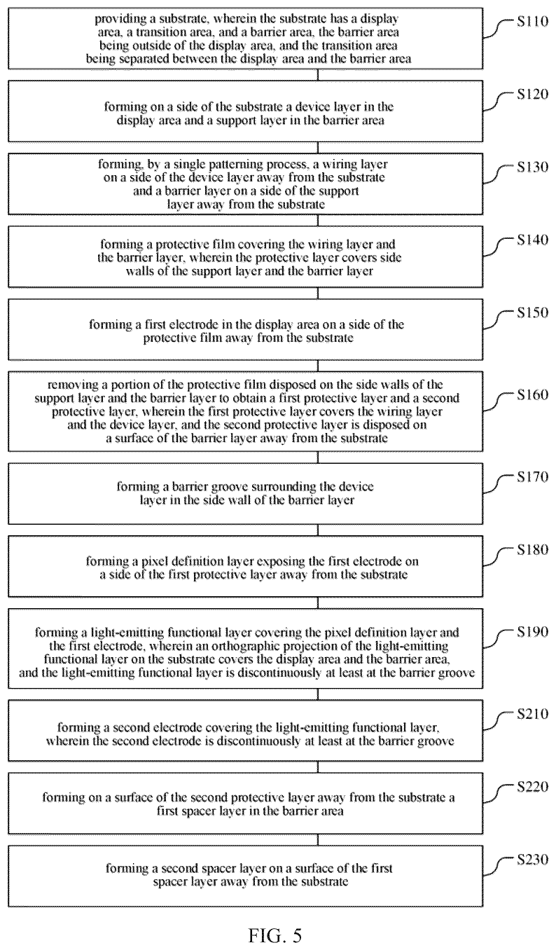

In some embodiments of the present disclosure, the manufacturing method of the present disclosure may further include steps S220 and S230, as shown in FIG. 5.

Step S220, forming on a surface of the second protective layer away from the substrate a first spacer layer in the barrier area.

Step S230, forming a second spacer layer on a surface of the first spacer layer away from the substrate.

The height of the barrier structure can be increased by the first spacer layer and the second spacer layer to increase the climbing difficulty of the light-emitting layer and to facilitate blocking of the light-emitting layer, and the specific structure and material can be referred to the implementation of the display panel, which will not be described in detail herein. Further, the first spacer layer and the first electrode are formed by a single patterning process; and the second spacer layer and the pixel definition layer are formed by a single patterning process.

Further, the manufacturing method of the present disclosure may include: forming an encapsulation layer covering the light-emitting layer and the barrier structure.

The structure and related processes of the display panel have been described in the embodiments of the present disclosure, and the relevant details of the manufacturing method of the present disclosure can be referred to the embodiments of the display panel and will not be repeated herein.

It should be noted that although the various steps of the manufacturing method in the present disclosure are illustrated in the accompanying drawings in a particular order, it is not required or implied that the steps must be performed in that particular order or that all of the steps shown must be performed in order to achieve the desired result. Additional or alternatively, certain steps may be omitted, or multiple steps may be combined to be performed as a single step, and/or a single step may be decomposed into multiple steps to be performed, etc.

According to some embodiments of the present disclosure, a display device is further provided, which includes a display panel of any of the above embodiments. The structure of the display panel has been described in detail in the embodiments of the display panel above and will not be repeated herein. The display device of the present disclosure may be an electronic device having an image display function such as a cell phone, a tablet computer, a television, and so on, and will not be enumerated herein.

Other embodiments of the present disclosure will be readily apparent to those skilled in the art upon consideration of the specification and practice of the invention disclosed herein. This application is intended to cover any variation, use, or adaptation of the present disclosure that follows the general principles of the present disclosure and includes commonly known or customary technical means in the art not disclosed herein. The specification and embodiments are to be considered exemplary only, and the true scope and spirit of the disclosure is indicated by the appended claims.

1. A display panel, comprising:
a substrate having a display area, a transition area, and a barrier area, the barrier area being outside of the display area, and the transition area being separated between the display area and the barrier area:
a driver layer, on a side of the substrate and within the display area, comprising a device layer, a wiring layer and a first protective layer: wherein the wiring layer is on a side of the device layer away from the substrate, and the first protective layer covers the wiring layer and the device layer:
a barrier structure, on the same side of the substrate as the driver layer and in the barrier area, surrounding the driver layer and comprising a support layer, a barrier layer and a second protective layer: wherein the barrier layer is on a side of the support layer away from the substrate and in a different area of a same film layer than the wiring layer, and a side wall of the barrier layer is provided with a barrier groove surrounding the driver layer; and the second protective layer is on a surface of the barrier layer away from the substrate and in a different area of a same protective film than the first protective layer; and
a light-emitting layer covering the driver layer and the barrier structure and being discontinuously at least at the barrier groove.

2. The display panel of claim 1, wherein the barrier layer is provided with barrier grooves on the side wall close to the driver layer and on the side wall away from the driver layer:
each of the wiring layer and the barrier layer comprises a first metal layer, a second metal layer, and a third metal layer stacked in sequence along a direction away from the substrate:
the first metal layer and the third metal layer are of a same material which is different from a material of the second metal layer; and
in the barrier layer, a boundary of an orthographic projection of the second metal layer on the substrate is within boundaries of orthographic projections of the first metal layer and the third metal layer on the substrate to form the barrier groove.

3. The display panel of claim 1, wherein the support layer comprises:
a first insulation layer on a side of the substrate;
a first conductive layer on a surface of the first insulation layer away from the substrate; and
a second insulation layer covering a surface of the first conductive layer away from the substrate; and
wherein the barrier layer is on a side of the second insulation layer away from the substrate.

4. The display panel of claim 3, wherein the support layer further comprises:
a third insulation layer covering a surface of the second insulation layer away from the substrate; and
wherein the barrier layer is on a side of the third insulation layer away from the substrate.

5. The display panel of claim 4, wherein the support layer further comprises:
a second conductive layer on a surface of the third insulation layer away from the substrate; and
a fourth insulation layer covering a surface of the second conductive layer away from the substrate; and
wherein the barrier layer is on a surface of the fourth insulation layer away from the substrate.

6. The display panel of claim 5, wherein the barrier structure further comprises:
a first spacer layer on a surface of the second protective layer away from the substrate; and
a second spacer layer on a surface of the first spacer layer away from the substrate.

7. The display panel of claim 6, wherein the device layer comprises:
an active layer on a side of the substrate;
a first gate insulation layer covering the active layer and being in a different area of a same film layer than the first insulation layer:
a gate electrode on a surface of the first gate insulation layer away from the substrate, an orthographic projection of the gate electrode on the substrate at least partially overlapping with an orthographic projection of the active layer on the substrate, the gate electrode being in a different area of a same film layer than the first conductive layer:
a second gate insulation layer covering the gate electrode and the first gate insulation layer and being in a different area of a same film layer than the second insulation layer:
an interlayer dielectric layer covering the second gate insulation layer and being in a different area of a same film layer than the third insulation layer:
a source and drain layer, on a surface of the interlayer dielectric layer away from the substrate, comprising a source electrode and a drain electrode connected to the active layer, the source and drain layer being in a different area of a same film layer than the second conductive layer:
a first planarization layer covering the source and drain layer and the interlayer dielectric layer; and
a passivation layer covering the first planarization layer and being in a different area of a same film layer than the fourth insulation layer;
wherein the wiring layer is on a surface of the passivation layer away from the substrate and connected to the source and drain layer.

8. The display panel of claim 17, wherein the film layer in which the first gate insulation layer and the first insulation layer are disposed covers the transition area; and the film layer in which the second gate insulation layer and the second insulation layer are disposed covers the transition area.

9. The display panel of claim 1, wherein a material of the protective film comprises at least one of silicon nitride and silicon oxide.

10. The display panel of claim 1, wherein a thickness of the protective film is greater than or equal to 0.1 μm, and is less than or equal to 0.2 μm.

11. A method for manufacturing a display panel, comprising:
providing a substrate, wherein the substrate has a display area, a transition area, and a barrier area, the barrier area being outside of the display area, and the transition area being separated between the display area and the barrier area;
forming on a side of the substrate a device layer in the display area and a support layer in the barrier area;
forming, by a single patterning process, a wiring layer on a side of the device layer away from the substrate and a barrier layer on a side of the support layer away from the substrate;
forming a protective film covering the wiring layer and the barrier layer, wherein the protective layer covers side walls of the support layer and the barrier layer;
forming a first electrode in the display area on a side of the protective film away from the substrate;
removing a portion of the protective film disposed on the side walls of the support layer and the barrier layer to obtain a first protective layer and a second protective layer, wherein the first protective layer covers the wiring layer and the device layer, and the second protective layer is disposed on a surface of the barrier layer away from the substrate;
forming a barrier groove surrounding the device layer in the side wall of the barrier layer;
forming a pixel definition layer exposing the first electrode on a side of the first protective layer away from the substrate;
forming a light-emitting functional layer covering the pixel definition layer and the first electrode, wherein an orthographic projection of the light-emitting functional layer on the substrate covers the display area and the barrier area, and the light-emitting functional layer is discontinuously at least at the barrier groove; and
forming a second electrode covering the light-emitting functional layer, wherein the second electrode is discontinuously at least at the barrier groove.

12. The method of claim 11, wherein forming, by a single patterning process, a wiring layer on a side of the device layer away from the substrate and a barrier layer on a side of the support layer away from the substrate, comprises:
forming a first metal layer on the side of the device layer away from the substrate and on the side of the support layer away from the substrate;
forming a second metal layer on a surface of the first metal layer away from the substrate, wherein a material of the second metal layer is different from a material of the first metal layer;
forming a third metal layer on a surface of the second metal layer away from the substrate, wherein a material of the third metal layer is the same as the material of the first metal layer; and
patterning the first metal layer, the second metal layer, and the third metal layer to form the wiring layer on the side of the device layer away from the substrate and the barrier layer on the side of the support layer away from the substrate.

13. The method of claim 19, further comprising:
forming a first spacer layer on a surface of the second protective layer away from the substrate; and
forming a second spacer layer on a surface of the first spacer layer away from the substrate.

14. The method of claim 13, wherein the first spacer layer and the first electrode are formed by a single patterning process; and the second spacer layer and the pixel definition layer are formed by a single patterning process.

15. A display device, comprising the display panel of claim 1.

16. The display panel of claim 7, wherein the driver layer further comprises a second planarization layer covering the first protective layer.

17. The display panel of claim 16, wherein the light-emitting layer comprises:
a first electrode on a surface of the second planarization layer away from the substrate and connected to the wiring layer, the first electrode being in a different area of a same film layer than the first spacer layer;
a pixel definition layer on the surface of the second planarization layer away from the substrate and exposing the first electrode, the pixel definition layer being in a different area of a same film layer than the second spacer layer;
a light-emitting functional layer covering the pixel definition layer, the first electrode, and the second spacer layer, and being discontinuously at least at the barrier groove; and
a second electrode covering the light-emitting functional layer and being discontinuously at least at the barrier groove.

18. The display panel of claim 1, further comprising:
an encapsulation layer covering the light-emitting layer and the barrier structure.

19. The method of claim 12, wherein forming a barrier groove surrounding the device layer in the side wall of the barrier layer, comprises:
etching the side wall of the barrier layer by a wet etching process until a boundary of an orthographic projection, of the second metal layer of the barrier layer on the substrate, is within boundaries of orthographic projections, of the first metal layer and the third metal layer on the substrate, to form the barrier groove.

20. The method of claim 11, further comprising: forming an encapsulation layer covering the light-emitting layer and the barrier structure.
